(19) United States
(12) Patent Application Publication
(10) Pub. No.: US 2011/0000702 A1
(43) Pub. Date: Jan. 6, 2011

(54) CIRCUIT BOARD

(75) Inventor: Akira Oikawa, Tokyo (JP)

Correspondence Address: Ditthavong Mori & Steiner, P.C., 918 Prince Street, Alexandria, VA, 22314, US

(73) Assignee: Sumitomo Bakelite Co., Ltd., Tokyo (JP)

(21) Appl. No.: 12/920,110

(22) PCT Filed: Mar. 10, 2009
(86) PCT No.: PCT/JP2009/054543

§ 371 Date: Aug. 30, 2010

(30) Foreign Application Priority Data
Mar. 25, 2008 (JP) 2008-077077

(51) Int. Cl. H05K 1/03

(52) U.S. Cl. 174/255

(57) ABSTRACT

A signal line (2) is formed on one surface of a base substrate (1), and a cover lay film (3) is laminated further. A plurality of projections (4) made of an insulating material are formed at substantially regular intervals vertically and laterally on an upper surface of the above-mentioned cover lay film and a ground layer (5), for example, made of a silver paste is formed on the above-mentioned cover lay film except for the arranged position of each of the above-mentioned projections.

In this case, a film thickness of the ground layer made of said conductive paste is formed to be less than a height of a top of said projection arranged at an insulating layer, so that an openings (gaps) substantially in the shape of a mesh can be formed at the ground layer made of the conductive paste because of the existence of the projection.

Thus, it is possible to provide a circuit board achieving the similar effect to that of a ground plane having gaps substantially in the shape of a mesh.

### TECHNICAL FIELD

The present invention relates to a circuit board in which signal lines are opposed to a ground layer through an insulating layer.

### BACKGROUND ART

For example, a circuit board having mounted thereon a device which operates in a high frequency band needs to match a characteristic impedance (hereinafter also referred to as Z₀) of a signal transmission line (hereinafter also referred to as signal line) to input-and-output impedances of the above-mentioned device in order to suppress reflection of a signal and generation of wave distortion.

As described above, in order to adjust the characteristic impedance of the signal transmission line, a strip structure or a micro-strip structure is employed in which the signal transmission lines (strip lines) with a suitable pattern width are opposed to the ground layer through an insulator layer with a suitable thickness.

The above-mentioned ground layer in the above-mentioned circuit board structure acts as an electric reference plane which specifies the characteristic impedance of the signal transmission lines. In general, the characteristic impedance is often selected to be around 50Ω in the case of a single end and selected to be around 100Ω the case of differential transmission.

On the other hand, the characteristic impedance in the above-mentioned circuit board becomes a value approximated by a square root of a ratio (reactance L/capacity C) of the reactance L per unit length of the signal transmission line to electrostatic capacitance C per unit area between the above-mentioned signal transmission line and the ground layer.

Incidentally, in recent years, a thin flexible circuit-board (FPC) has often been used as a circuit board for mounting the above-mentioned device. In the case where such a circuit board is employed, a layer distance between the signal transmission line and the above-mentioned ground layer is naturally small (thin), and a value of the electrostatic capacitance C increases substantially in inverse proportion to the above-mentioned layer distance.

Therefore, in the above-mentioned thin FPC, in order to obtain the above-mentioned desired Z₀, a means for inhibiting the above-mentioned electrostatic capacitance C from increasing has to be employed by forming a signal transmission line with a narrower (thinner) width compared with a circuit board, such as a conventional rigid circuit board, which has a large layer distance.

Thus, when trying to form and make signal lines thin in order to obtain the desired Z₀, it may have to be so thin that processing of the signal lines is difficult. Further, even if the processing of signal lines is possible, degrees of the processing accuracy and line width deviation become larger as the signal lines are thinner, and accordingly deviation of Z₀ increases.

For this reason, there arises a problem in that a signal may be reflected and a wave may be distorted at a part of the signal line where the above-mentioned Z₀ changes greatly. Further, since wiring resistance of the signal lines becomes high, there is another problem that the higher signal frequency supplied thereto may cause a transmission characteristic to be worse.

Then, in order to solve the above-mentioned technical problems, one proposal is made such that part of a copper layer of the above-mentioned ground layer formed as a so-called solid pattern layer is removed to have mesh-like rectangular holes, and an overlapping area between the ground layer and the signal lines per unit area is substantially reduced, to thereby secure the width of the above-mentioned signal lines. This is disclosed in Patent Document 1 listed below.

Patent Document 1: Japanese Patent Application Publication No. H7-321463

Incidentally, it has been increasingly necessary to cope with the above-mentioned Z₀, for FPC to be bent when used for an electronic device which has a foldable structure etc., like a mobile phone, and for FPC which requires electromagnetic wave shield and is specified such that the ground layer is formed on a resist layer etc., such as a cover lay film etc.

In the above-mentioned FPC to be bent in use, since a double-sided wiring structure damages the flexibility badly, it is effective to add a flexible and very thin shield layer and to design a characteristic impedance by using the shield layer as a ground plane. Further, also in the thin substrate which needs the electromagnetic wave shield, it is effective to design the characteristic impedance by using the shield layer as the ground similarly.

As examples of a shield material which constitutes the above-mentioned shield layer, there may be mentioned two types in general. One is such that a conductive paste having dispersed therein conductive particles, represented by silver paste, is printed and cured, and the other is such that a metal layer is formed as a film on an organic film etc. by way of vacuum deposition or other methods and a conductive adhesive is applied.

While, the ground plane having gaps, for example in the shape of a mesh, can be formed by printing in order to obtain the desired Z₀ by using pastes like the former, but there arises a problem that it tends to be greatly suffered from blurring, bleeding, etc. due to the printing, which leads to reduction in area accuracy.

Further, as for the latter shield film having formed thereon the metal layer as a film by vacuum deposition etc., it is impossible to form the ground plane having gaps, for example in the shape of a mesh, unless unreally fine punch processing which is not suitable for mass production is carried out.

### DISCLOSURE OF THE INVENTION

### Object of the Invention

The present invention arises in view of the above-mentioned technical problems and aims at providing a circuit board which achieves substantially the same action as that of a ground plane having gaps, for example in the shape of a mesh, without printing a mesh pattern or without carrying out punch processing etc., to thereby improve accuracy of a characteristic impedance.

### Means to Solve the Problems

The circuit board in accordance with the present invention made in order to solve the above-mentioned problems is a circuit board in which a ground layer is opposed to a signal line through an insulating layer, characterized in that a projection formed of an insulating material is arranged at a surface of the insulating layer in which the above-mentioned ground layer is formed, the above-mentioned ground layer made of a conductive material is formed on a surface of the above-mentioned insulating layer except for, at least, the arranged position of the above-mentioned projection, and a characteristic impedance of the above-mentioned signal line is adjusted by the arrangement of the above-mentioned projection disposed on the surface of the above-mentioned insulating layer.

In this case, in one preferred embodiment, it is arranged that the above-mentioned ground layer is made of a conductive paste, and a film thickness of the ground layer made of the above-mentioned conductive paste is formed to be less than a height of a top of the above-mentioned projection arranged at the above-mentioned insulating layer, so that the above-mentioned projection allows the above-mentioned ground layer made of the conductive paste to open in the shape of a mesh.

Further, in another preferred embodiment, it is arranged that the above-mentioned ground layer is made of a conductive paste, a film thickness of the ground layer made of the above-mentioned conductive paste is formed to be greater than a height of a top of the above-mentioned projection arranged at the above-mentioned insulating layer so that the above-mentioned ground layer made of the conductive paste may cover the above-mentioned projection, and a distance from the above-mentioned ground layer to the above-mentioned signal line is increased in an arranged position of the above-mentioned projection, so that an electrostatic capacitance between the signal line and the ground layer is set to be low at the increased portion.

Further, in another preferred embodiment, it is arranged that a conductive thin film in which a metal material is formed as a film on a film substrate in advance is used as the above-mentioned ground layer, the ground layer formed of the above-mentioned conductive thin film is laminated to a surface of the insulating layer in which the above-mentioned projection is arranged so that a distance from the above-mentioned ground layer to the above-mentioned signal line is increased in an arranged position of the above-mentioned projection, and an electrostatic capacitance between the ground layer and the signal line is set to be low at the increased portion.

### EFFECT OF THE INVENTION

According to the circuit boards with the above-mentioned structures, the projection is formed of the insulating material at the surface of the insulating layer in which the ground layer is formed, and the conductive paste is printed, as one means, on the surface of the insulating layer where the above-mentioned projection is formed. In this case, the film thickness of the above-mentioned conductive paste is arranged to be less than a height of the top of the above-mentioned projection formed at the insulating layer, so that substantially mesh-like openings (gaps) can be formed at the ground layer made of the conductive paste because of the existence of the above-mentioned projections. Thus, it becomes possible to adjust the characteristic impedance of signal lines.

Further, even if the film thickness of the above-mentioned conductive paste is arranged to cover the top of the above-mentioned projection formed at the insulating layer, the distance from the ground layer to signal line can be increased in a position where the above-mentioned projection is formed. In other words, since the electrostatic capacitance between the ground layer and signal line can be set to be low in the position where the above-mentioned projection is formed, it becomes possible to adjust the characteristic impedance of signal lines similarly.

Furthermore, in the circuit board in accordance with the present invention, the conductive thin film in which the metal material is formed as a film on the film substrate beforehand can be used as the ground layer. Also in this case, the distance from the ground layer to the signal line can be increased in the arranged position of the above-mentioned projection by laminating the ground layer of the above-mentioned conductive thin film to the surface of the insulating layer in which the projection is formed. Thus, since the electrostatic capacitance between the ground layer and the signal line can be similarly set to be low in the position where the projection is formed, it becomes possible to adjust the characteristic impedance of the signal lines.

Even if any one of the above-mentioned means is employed, the ground layer having substantially the same function as that in the case where the gaps, for example in the shape of a mesh, are provided can be obtained without printing the mesh pattern or without carrying out the punch processing etc.

Thus, when obtaining the desired characteristic impedance, the comparatively large line width of the signal line can be achieved so that the deviation in line width can be controlled, accordingly it is possible to inhibit the generation of the deviation in Z₀. Further, it becomes possible to provide a circuit board which can also remove the cause of the deviation of Z₀ due to blurring or bleeding when printing the mesh pattern and can increase the accuracy of the characteristic impedance of signal lines.

### BRIEF DESCRIPTION OF THE DRAWINGS

FIG. 1 It is a plan view showing a first preferred embodiment of a circuit board in accordance with the present invention.

FIG. 2 It is a sectional view in the direction of an arrow along A-A line in FIG. 1.

FIG. 3 It is a plan view showing a second preferred embodiment of the circuit board in accordance with the present invention.

FIG. 4 It is a plan view showing a third preferred embodiment similarly.

FIG. 5 It shows a fourth preferred embodiment of the circuit board in accordance with the present invention and is a sectional view in the direction of an arrow along C-C line in FIG. 6.

FIG. 6 It is a sectional view in the direction of an arrow along B-B line in FIG. 5.

FIG. 7 It is a sectional view showing a fifth preferred embodiment of the circuit board in accordance with the present invention.

FIG. 8 It is a sectional view in a situation where a shield film is laminated similarly.

### DESCRIPTION OF REFERENCE NUMERALS

1 base substrate
2 signal line
3 insulating layer (cover lay film)
4 projection
5 ground layer
7 film substrate
8 conductive thin film (ground layer)

### BEST MODE FOR CARRYING OUT THE INVENTION

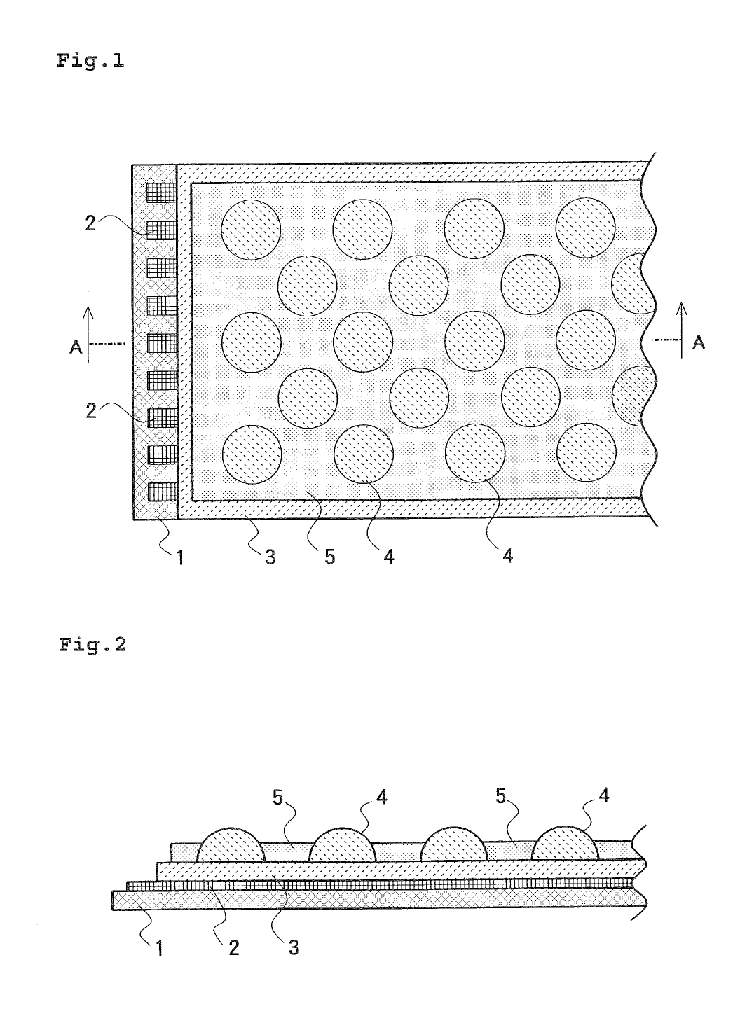

FIGS. 1 and 2 are schematic views showing a first preferred embodiment in which a circuit board in accordance with the present invention is applied to a flexible printed circuit board, FIG. 1 shows it in plan view, and FIG. 2 shows it in sectional view in the direction of an arrow along A-A line in FIG. 1.

Reference numeral 1 in FIGS. 1 and 2 indicates a film-like base substrate formed of an insulating material, and a plurality of signal lines 2 formed of copper foil are arranged on one surface (upper surface shown in FIG. 2) of the base substrate 1. Further, an insulating layer 3 is laminated to the base substrate 1 so as to cover the above-mentioned signal lines 2.

For example, a polyester film, a polyimide film, a liquid crystal polymer film, etc. can be used for the above-mentioned base substrate 1. Of these, the polyimide film is desirable since it is highly resistant to heat and sufficiently able to withstand a soldering temperature when mounting components and to provide a stable performance against environmental changes after being actually installed into a device. In addition, the base substrate 1 with a thickness of 12.5 to 50 μm is usually used.

Further, the copper foil for forming the signal lines 2 may be either electrolytic copper foil or rolled copper foil. Although the thickness of the copper foil is not particularly limited, it is suitably determined within a range of 10 to 35 μm. In a flexible printed circuit board, adhesion between the base substrate 1 and the signal lines 2 is not particularly limited, but either the adhesion using an adhesive or the adhesion without using an adhesive can be employed.

Further, the above-mentioned insulating layer 3 is not particularly limited, but, for example, a cover lay film (in the following description, the insulating layer 3 may also be referred to as a cover lay film) which is formed of a film and an adhesive can be suitably employed.

Although not particularly limited as a material for the above-mentioned cover lay film, the polyester film and the polyimide film can be used, for example. Of these, it is preferable that the same material as that for the base substrate 1 is used since it is possible to prevent a product from curling or warping in a heating process at the time of manufacture. Further, thermosetting resins, such as an epoxy resin and acrylic resin, can be used as the adhesive.

Furthermore, a plurality of projections 4 formed of the insulating material are arranged on the upper surface of the above-mentioned cover lay film 3. In addition, in the preferred embodiment shown in FIGS. 1 and 2, the above-mentioned projections 4 are formed substantially in the shape of a hemisphere and arranged at regular intervals vertically and laterally on the upper surface of the cover lay film 3. The above-mentioned projection 4 can be obtained in such a way that a paste-like material with a relatively high viscosity, for example, a thermosetting resin, such as an epoxy resin etc. is applied onto the cover lay film 3 by means of a dispenser or screen printing and heated to cure.

Then, a ground layer 5 made of a conductive material is formed on a surface of the above-mentioned cover lay film 3 except for the arranged positions of the above-mentioned projections 4. In addition, in the preferred embodiment shown in FIGS. 1 and 2, the above-mentioned ground layer 5 can be obtained in such a way that a conductive paste is applied by way of printing etc. and cured. As for the above-mentioned conductive paste, a silver paste (for example) can suitably be employed. Instead of the above-mentioned silver paste, a paste in which conductive particles made of copper or carbon are dispersed can also be used.

At this time, a film thickness of the ground layer made of the conductive paste is controlled and formed to be less (lower) than the height of the top of the above-mentioned projection 4 formed on the above-mentioned cover lay film 3, so that the top (central part) of each projection 4 protrudes out of the upper surface of the ground layer 5 made of the conductive paste. Therefore, the ground layer 5 is arranged to open substantially in the shape of a mesh because of the existence of each of the above-mentioned projections 4 arranged on the cover lay film 3.

Thus, the above-mentioned signal line 2 which is opposed to the ground layer 5 through the cover lay film 3 can reduce electrostatic capacitance per unit area between itself and the ground layers 5. Therefore, according to the arrangement of the above-mentioned projections 4 disposed on the cover lay film 3, it is possible to adjust the characteristic impedance of the signal lines 2 and to obtain the operational effect as described in the column of Effect of the Invention above.

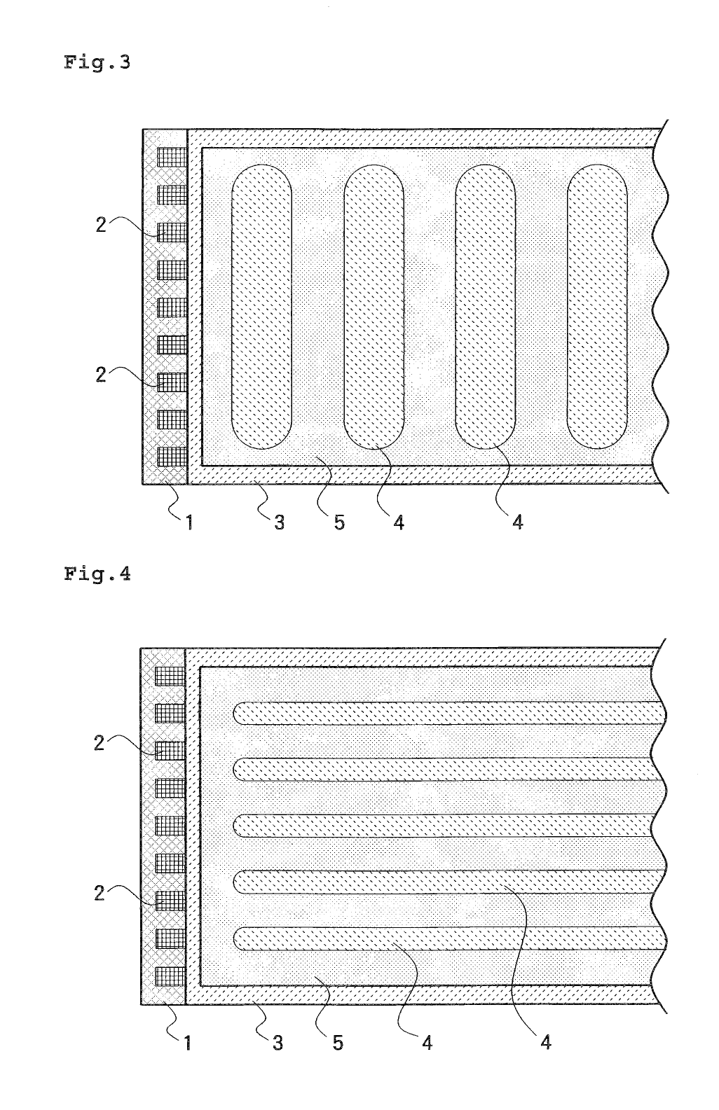

FIG. 3 shows in plan view a second preferred embodiment of the circuit board in accordance with the present invention. Further, in FIG. 3, parts which achieve the same function as the respective parts shown in FIG. 1 already described are identified by the same reference numerals, and therefore the detailed description thereof will not be repeated.

In the second preferred embodiment shown in FIG. 3, the projections 4 made of the insulating material are formed in the shape of a long island and orthogonally to the signal lines 2. Also in this second preferred embodiment, the film thickness of the ground layer 5 made of the conductive paste is arranged to be less (lower) than the heights of the tops of the above-mentioned projections 4 formed on the above-mentioned cover lay film 3. Therefore, the top in a longitudinal direction of each projection 4 protrudes out of the upper surface of the ground layer 5 made of the conductive paste.

According to the second preferred embodiment shown in FIG. 3, gaps which open in the shape of a long slot are formed orthogonally to the signal lines 2 on the ground layer 5 because of the existence of each of the above-mentioned projections 4 arranged on the cover lay film 3. Therefore, also in this preferred embodiment, according to the arrangement of the above-mentioned projections 4 disposed on the cover lay film 3, it is possible to adjust the characteristic impedance of the signal lines 2 and to obtain the operational effect similar to that in the first preferred embodiment as previously described.

FIG. 4 shows in plan view a third preferred embodiment of the circuit board in accordance with the present invention. Further, in FIG. 4, parts which achieve the same function as the respective parts shown in FIG. 1 already described are identified by the same reference numerals, and therefore the detailed description thereof will not be repeated.

In the third preferred embodiment shown in FIG. 4, the projections 4 made of the insulating material are formed in the shape of a stripe so that they may be substantially parallel to the signal lines 2. Also in this preferred embodiment, the film thickness of the ground layer 5 made of the conductive paste is arranged to be lower (less) than the heights of the tops of the above-mentioned projections 4 formed on the above-mentioned cover lay film 3. Therefore, the top in a longitudinal direction of each projection 4 protrudes out of the upper surface of the ground layer 5 made of the conductive paste.

Also in the third preferred embodiment shown in FIG. 4, gaps which open in the shape of a long slot are formed in parallel to the signal lines 2 on the ground layer 5 because of the existence of each of the above-mentioned projections 4 arranged on the cover lay film 3. Therefore, also in this preferred embodiment, according to the arrangement of the above-mentioned projections 4 disposed on the cover lay film 3, it is possible to adjust the characteristic impedance of the signal lines 2 and to obtain the operational effect similar to that in the first preferred embodiment.

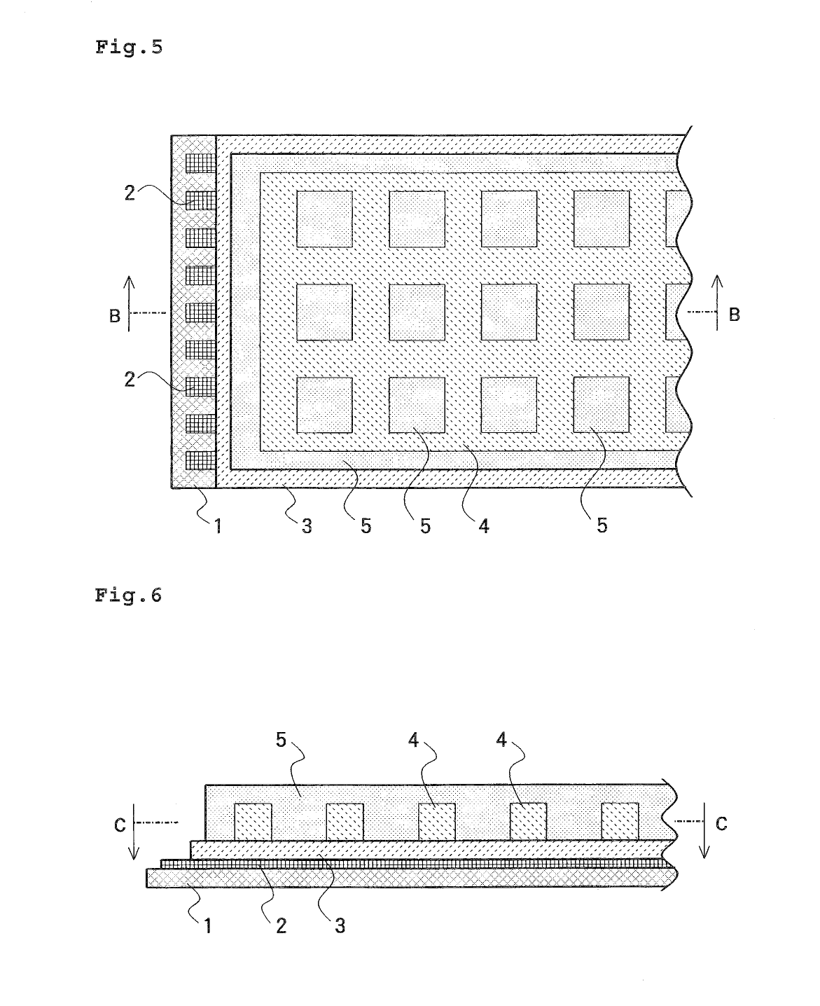

FIGS. 5 and 6 show a fourth preferred embodiment of the circuit board in accordance with the present invention, and FIG. 5 shows it in sectional view in the direction of an arrow along C-C line in FIG. 6, and FIG. 6 shows it in sectional view in the direction of an arrow along B-B line in FIG. 5. Further, also in FIGS. 5 and 6, parts which achieve the same function as the respective parts shown in FIGS. 1 and 2 already described are identified by the same reference numerals, and therefore the detailed description thereof will not be repeated.

In this preferred embodiment, the projection 4 formed on the cover lay film 3 is formed in the shape of a grid which is continuous vertically and horizontally, and square openings (pits) are formed and arranged in the shape of a matrix. Further, the ground layer 5 is formed by arraigning the film thickness of the layer made of the conductive paste to be greater (higher) than a height of the above-mentioned projection. Therefore, the ground layer 5 made of the conductive paste is allowed to be electrically conductive over the whole surface.

As described above, the above-mentioned projection arranged in the shape of a continuous grid is brought into contact with the cover lay film 3 at intervals as shown in FIG. 6, and the conductive paste is entered into the square openings formed at the projection 4. Therefore, in the arranged position of the projection 4 as shown in FIG. 6, a distance from the signal line 2 to the ground layer 5 is increased, so that the electrostatic capacitance between the signal line and the ground layer is set to be low at the increased portion.

Accordingly, an effect substantially equivalent to that of through holes formed in the shape of a mesh at the ground layer is obtained in the position of the projection 4 in contact with the cover lay film 3. Therefore, also in this preferred embodiment, due to the arrangement of the above-mentioned projection 4 disposed on the cover lay film 3, it is possible to adjust the characteristic impedance of the signal lines 2, and to obtain the same operational effect as that of the first preferred embodiment.

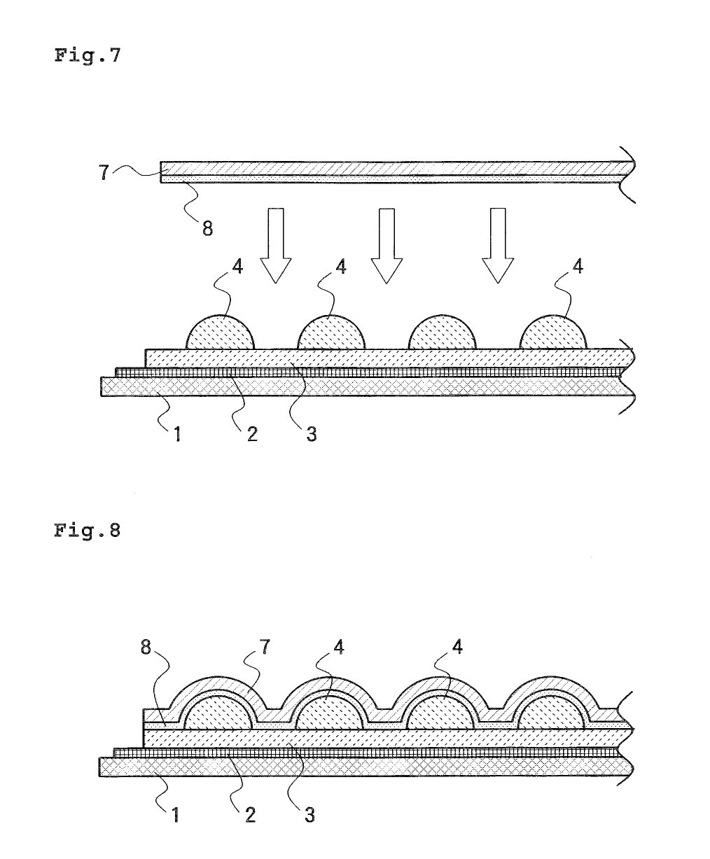

FIGS. 7 and 8 show in sectional view a fifth preferred embodiment of the circuit board in accordance with the present invention. Further, in FIGS. 7 and 8, parts which achieve the same function as the respective parts shown in FIG. 2 already described are identified by the same reference numerals, and therefore the detailed description thereof will not be repeated.

This preferred embodiment is different from each of the preferred embodiments as described previously, in that a conductive thin film in which a metal material is formed as a film on a film substrate in advance is used as the ground layer. In other words, in this preferred embodiment, as shown in FIG. 7, it is arranged that a conductive thin film 8 is formed at one surface of a film substrate 7 by forming the metal material as a film by way of vacuum deposition or other means, so that this conductive thin film 8 may function as the ground layer.

The film substrate 7 (hereinafter, also referred to as shield film) having formed therein the above-mentioned conductive thin film 8 is laminated onto the cover lay film 3 in which the projections 4 are arranged by means of an adhesive (not shown). At this time, it becomes necessary to laminate the above-mentioned shield film onto the cover lay film 3 by using a vacuum press method or other methods so that it may sufficiently enter except for the arranged positions of the projections 4.

Thus, the conductive thin film 8 which constitutes the shield film comes into close contact with the cover lay film 3 except for each projection 4 and the arranged positions of the projections as shown in FIG. 8. According to this structure, in the arranged position of the projection 4, the distance from the signal line 2 to the ground layer formed of the conductive thin film 8 is increased, so that the electrostatic capacitance between the signal line and the ground layer is set to be low at the increased portion.

Accordingly, an effect substantially equivalent to that of through holes formed in the shape of a mesh at the ground layer is obtained in the arranged position of the above-mentioned projection 4. Therefore, also in this preferred embodiment, due to the arrangement of the above-mentioned projections 4 disposed on the cover lay film 3, it is possible to adjust the characteristic impedance of the signal lines 2, and to obtain the same operational effect as that of the first preferred embodiment.

The example in which the thermosetting resin, such as an epoxy resin, is used for the projection 4 arranged on the cover lay film 3 is described in the preferred embodiment above; as for the means for forming the projection, perforations in the shape of a small round or of a long and slender shape are formed in the thin film with adhesive etc., which is laminated to the cover lay film, so that the structure which achieves the same function as that of the projections 4 shown in FIGS. 1-4 can be obtained.

Further, as for another means for forming the projection, the thin film etc. with adhesive having formed therein small round holes, square or slit-shaped openings by a perforation process is laminated to the cover lay film, so that the structure which achieves the same function as that of the projections 4 shown in FIGS. 5 and 6 can be obtained.

### INDUSTRIAL APPLICABILITY

The circuit board in accordance with the present invention can be used for circuit boards which achieve the function to control the characteristic impedance, such as a printed circuit board, a flexible printed circuit board, and a multilayer flexible printed circuit board. In particular, it can be adopted suitably for a circuit board for mounting a device which operates in a high frequency band.

1. A circuit board in which a ground layer is opposed to a signal line through an insulating layer,
a projection formed of an insulating material is arranged at a surface of the insulating layer in which said ground layer is formed, and said ground layer made of a conductive material is formed on a surface of said insulating layer except for, at least, the arranged position of said projection, and
a characteristic impedance of said signal line is adjusted by the arrangement of said projection disposed on the surface of said insulating layer, characterized in that
said ground layer is made of a conductive paste, and a film thickness of the ground layer made of said conductive paste is formed to be less than a height of a top of said projection arranged at said insulating layer, so that said projection allows said ground layer made of the conductive paste to open in the shape of a mesh.

2. (canceled)

3. A circuit board in which a ground layer is opposed to a signal line through an insulating layer, a projection formed of an insulating material is arranged at a surface of the insulating layer in which said ground layer is formed, and said ground layer made of a conductive material is formed on a surface of said insulating layer except for, at least, the arranged position of said projection, and a characteristic impedance of said signal line is adjusted by the arrangement of said projection disposed on the surface of said insulating layer, characterized in that
said ground layer is made of a conductive paste, a film thickness of the ground layer made of said conductive paste is formed to be greater than a height of a top of said projection arranged at said insulating layer so that said ground layer made of the conductive paste may cover said projection, and a distance from said ground layer to said signal line is increased in an arranged position of said projection, so that an electrostatic capacitance between the signal line and the ground layer is set to be low at the increased portion.

4. (canceled)
